(19) United States
(12) Patent Application Publication
(10) Pub. No.: US 2007/0155146 A1
(43) Pub. Date: Jul. 5, 2007

(54) Method for forming semiconductor wafer having insulator

(75) Inventor: Sung Ho Kwak, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,829

(22) Filed: Dec. 27, 2006

(30) Foreign Application Priority Data
Dec. 30, 2005 (KR) 10-2005-0134870

(51) Int. Cl. H01L 21/3205

(52) U.S. Cl. 438/585

(57) ABSTRACT

Provided is a method for forming a semiconductor wafer having an insulator. According to the method, an insulating layer pattern and a silicon germanium layer are formed on a wafer, and a structure similar to a SOI wafer is formed. Accordingly, since the thin insulating layer pattern exists between the surface of the wafer, in which a circuit is formed, and a lower layer thereof, parasitic capacitance is reduced and thus device performance can be improved. In addition, punch through due to a short channel effect, DIBL and leakage current can be solved as with the SOI wafer. Further, the insulating layer pattern is formed instead of an insulating layer formed on the SOI wafer, so that holes are prevented from being stacked in a neutral region. Consequently, a floating body effect can be prevented from occurring.

### BACKGROUND OF THE INVENTION

1. Field of the Invention

The present invention relates to technology for manufacturing a semiconductor device, and more particularly to a MOS transistor, which can solve punch through due to a short channel effect, DIBL and leakage current by forming an insulating layer pattern in the lower portion of a device by means of polymer and silicon germanium.

2. Description of the Related Art

With the high integration of a semiconductor device; the junction capacitance of a source and a drain in a device of less than submicron must be importantly considered together with gate capacitance, and functions as an important factor for determining the delay time of the device.

In addition, since the depth of source/drain junction may also cause Drain Induced Barrier Lowering (DIBL) in a device of less than submicron, reduce threshold voltage, and increase leakage current in an off state, research has been actively conducted in order to minimize the depth.

In the meantime, since the scaling of a Metal Oxide Semiconductor Field Effect Transistor (MOSFET) device does not conform to a constant field scaling principle, electric field in a device of less than submicron has approximated to a critical value. Further, Hot Carrier Injection (HCI) has occurred, in which mobility of moving electrons excessively increases due to high electric field. Furthermore, lifetime reduction has occurred due to deterioration of a gate oxide layer. The oxide layer is increasingly deteriorated due to holes injected into the gate oxide layer from a p-type wafer. In order to reduce the deterioration of the gate oxide layer, the number of generated holes must be reduced and the influence of a bulk wafer must be eliminated.

In order to solve these problems, Silicon On Insulator (SOI) MOSFET has been used. A SOI is a wafer with a structure in which a silicon single crystal layer is formed on an insulating layer. Since the SOI has a thin insulating layer between the wafer surface forming a circuit and a lower layer, parasitic capacitance is reduced and thus the device performance can be improved. Further, it can increase operation speed in the same voltage and lower supply voltage in the same speed.

An SOI MOSFET is a Partially Depleted (PD) SOI device in which a body becomes a neutral region when voltage is not applied to a gate. This device has the same channel design as that in a general bulk MOSFET, and its threshold voltage is not affected by an interfacial state between a buried oxide layer and a SOI layer. However, it has a severe floating body effect in which holes generated by collision transition are stacked in the neutral region and thus increase the potential of the body.

### SUMMARY OF THE INVENTION

Accordingly, the present invention is directed to a method for forming a semiconductor wafer having an insulator that substantially obviates one or more problems due to limitations and disadvantages of the related art.

Accordingly, the present invention has been made to solve the above-mentioned problems occurring in the prior art, and an object of the present invention is to provide a MOS transistor, which can solve punch through due to a short channel effect, DIBL and leakage current by forming an insulating layer pattern in the lower portion of a device by using polymer and silicon germanium.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

In accordance with an embodiment of the present invention, there is provided a method for forming a semiconductor wafer having an insulator, the method including: forming an insulating layer on a silicon wafer; forming a photo resist layer pattern on the insulating layer; forming a polymer around the photo resist layer pattern; etching the insulating layer by using the photo resist layer pattern and the polymer as a mask, thereby forming an insulating layer pattern; removing the photo resist layer pattern and the polymer through a wet process; and forming a silicon epilayer on the wafer including the insulating layer pattern.

It is preferred to form a polymer by using mixture gases including Carbon C and Fluorine F, which generate many polymers, in an etching apparatus capable of performing etching and polymer deposition processes. Further, in the wet process, it is preferred that the photo resist layer is removed using a SC-1 or SC-2 cleaning solution. Furthermore, it is preferred that the silicon epilayer is made from a silicon germanium layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIGS. 1 to 5 are sectional views according to steps illustrating a method for forming a semiconductor wafer having an insulator according to one embodiment of the present invention;

### DETAILED DESCRIPTION OF THE INVENTION

Hereinafter, an embodiment of the present invention will be described with reference to the accompanying drawings.

In the following description, technical contents will be omitted that are well known in the field of the present invention and have no direct relation to the present invention. This is for more clearly transferring the subject matter of the present invention by omitting an unnecessary description. For the same reason, some elements are enlarged, omitted or schematically illustrated in the accompanying drawings. The size of each element is not shown in the real size.

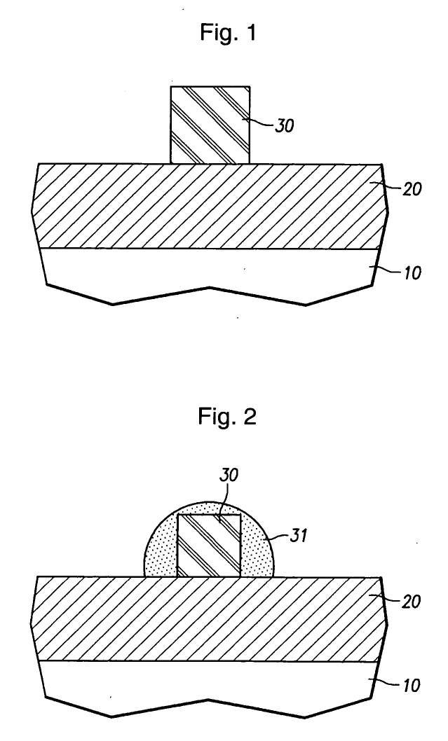

FIGS. 1 to 5 are sectional views according to steps illustrating a method for forming a semiconductor wafer having an insulator according to one embodiment of the present invention.

Referring to FIG. 1, an insulating layer 20 is formed on a silicon wafer 10. For example, the insulating layer 20 is formed using a thermal oxidation method, a Low Pressure Chemical Vapor Deposition (LPCVD) method, etc. Then, a photo resist layer pattern 30 is formed on the insulating layer 20.

As illustrated in FIG. 2, a polymer 31 is formed around the photo resist layer pattern 30. The polymer 31 is a photoresist layer-based (CₓHₓ, CₓH_{y}F_{z} or CₓF_{z}) polymer formed using mixture gases including carbon C and fluorine F (which may further include hydrogen H), which can generate many polymers, in an etching apparatus capable of performing etching and polymer deposition processes. Herein, while deposition and etching processes are simultaneously performed in the etching apparatus, the polymer 31 is formed only around the sidewall of the photo resist layer pattern 30, and the polymer 31 does not exist on the wafer 10 because the polymer 31 has been etched therefrom. Since the polymer 31 has a hemisphere shape because it is formed around the photo resist layer pattern 30.

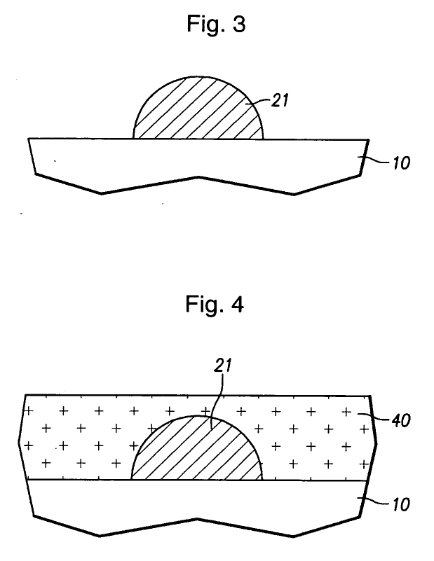

As illustrated in FIG. 3, the insulating layer 20 is etched by using the photoresist layer pattern 30 and the polymer 31 as a mask, so that an insulating layer pattern 21 is formed. The insulating layer pattern 21 may be shaped like a hemisphere.

Then, the photoresist layer pattern 30 and the polymer 31 are removed through a wet process. In the wet process, the photo resist layer is removed using a SC-1 or SC-2 cleaning solution. The SC-1 is a cleaning agent consisting of NH₄OH, H₂O₂ and H₂O, and the SC-2 is a cleaning agent consisting of H₂O₂ and H₂O.

As illustrated in FIG. 4, a silicon epilayer 40 (e.g., an epitaxial layer comprising silicon and which may further include germanium) is formed on the entire surface of the wafer 10 including the insulating layer pattern 21. For example, the silicon epilayer 40 is made from a silicon germanium SiGe layer 40. While the insulating layer pattern 21 and the silicon germanium layer 40 are formed on the wafer 10, a structure such as a SOI wafer is formed. That is, it is a structure in which a silicon layer is formed on an insulating layer as with the SOI wafer.

Accordingly, since the thin insulating layer pattern 21 exists between the surface of the wafer 10, in which a circuit is formed, and a lower layer thereof, parasitic capacitance is reduced and thus device performance can be improved. In addition, punch through due to a short channel effect, DIBL and leakage current can be solved as with the SOI wafer.

In the SOI wafer, a floating body effect occurs in which holes generated by collision transition are stacked in a neutral region and thus increase the potential of a body. However, the present invention prevents holes from being stacked in a neutral region by forming the insulating layer pattern 21 instead of an insulating layer, thereby preventing the floating body effect from occurring.

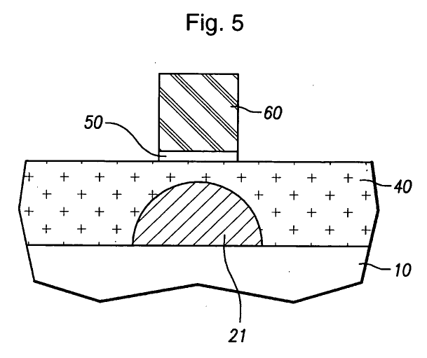

As illustrated in FIG. 5, a gate oxide layer 50 and a gate 60 are formed on the wafer 10 including the silicon germanium layer 40. Then, a general logic process is performed, so that a MOS transistor is formed.

According to a method for forming a semiconductor wafer having an insulator according to the present invention, while an insulating layer pattern and a silicon germanium layer are formed on a wafer, a structure similar to a SOI wafer is formed. Accordingly, since the thin insulating layer pattern exists between the surface of the wafer, in which a circuit is formed, and a lower layer thereof, parasitic capacitance is reduced and thus device performance can be improved. In addition, punch through due to a short channel effect, DIBL and leakage current can be solved as with the SOI wafer.

Further, According to a method for forming a semiconductor wafer having an insulator according to the present invention, an insulating layer pattern is formed instead of an insulating layer formed on a SOI wafer, so that holes are prevented from being stacked in a neutral region. Consequently, a floating body effect can be prevented from occurring.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for forming a semiconductor wafer having an insulator, the method comprising:
forming an insulating layer pattern on a silicon wafer;
forming an epitaxial layer comprising silicon over the silicon wafer including the insulating layer pattern; and
forming a transistor gate pattern on the epitaxial layer corresponding to the insulating layer pattern.

2. The method according to claim 1, wherein the epitaxial layer comprises silicon germanium.

3. The method according to claim 1, wherein the insulating layer pattern has a hemispherical shape.

4. The method according to claim 1, wherein the transistor gate pattern is formed over the insulating layer pattern.

5. The method according to claim 1, wherein the insulating layer pattern has a height of from 2000 to 10,000 Å.

6. The method according to claim 5, wherein the insulating layer pattern height is from 4000 to 8000 Å.

7. The method according to claim 5, wherein the insulating layer pattern has a width at its base of from 2000 to 10,000 Å.

8. The method according to claim 6, wherein the base width of the insulating layer pattern is from 3000 to 6000 Å.

9. A method for forming a semiconductor wafer having an insulator, the method comprising:
forming an insulating layer on a silicon wafer;
forming a photoresist pattern on the insulating layer;
forming a polymer around the photoresist pattern;
etching the insulating layer using the photoresist pattern and the polymer as a mask, thereby forming an insulating layer pattern;
removing the photoresist pattern and the polymer by a wet process; and
forming an epitaxial layer comprising silicon on the wafer including the insulating layer pattern.

10. The method according to claim 9, wherein the polymer comprises carbon and fluorine.

11. The method according to claim 10, wherein forming the polymer comprises introducing one or more gases including carbon and fluorine into an etching apparatus configured to perform etching and polymer deposition processes.

12. The method according to claim 9, wherein the wet process comprises removing the photoresist pattern with a SC-1 or SC-2 solution.

13. The method according to claim 9, wherein the epitaxial layer comprises silicon germanium.

14. The method according to claim 9, wherein the insulating layer pattern has a height of from 2000 to 10,000 Å and a width at its base of from 2000 to 10,000 Å.

15. The method according to claim 14, wherein the insulating layer pattern height is from 4000 to 8000 Å and the base width is from 3000 to 6000 Å.

16. The method according to claim 9, further comprising forming a transistor gate on the epitaxial layer over the insulating layer pattern, forming lightly doped drain extensions in the substrate adjacent to the gate, forming sidewall spacers on sides of the transistor gate, and forming source and drain terminals in the substrate on opposite sides of the sidewall spacers.

17. A transistor, comprising:
an insulating layer pattern on a silicon wafer;
an epitaxial layer comprising silicon on the silicon wafer including the insulating layer pattern; and
a transistor gate on the epitaxial layer over the insulating layer pattern.

18. The transistor according to claim 17, wherein the epitaxial layer comprises silicon germanium.

19. The transistor according to claim 17, wherein the insulating layer pattern has a rounded shape.

20. The transistor according to claim 17, further comprising lightly doped drain extensions in the silicon wafer adjacent to the gate, sidewall spacers on sides of the transistor gate, and source and drain terminals in the silicon wafer on opposite sides of the sidewall spacers.
